(19) United States
(12) Patent Application Publication
(10) Pub. No.: US 2025/0167021 A1
(43) Pub. Date: May 22, 2025

(54) DEPOSITION MONITOR FOR SEMICONDUCTOR MANUFACTURING SYSTEM

(71) Applicant: Axcelis Technologies, Inc., Beverly, MA (US)

(72) Inventors: Phillip Geissbuhler, Winchester, MA (US); Neil Bassom, Hamilton, MA (US); David Hoglund, Arlington, MA (US); Vladimir Romanov, Danville, NH (US)

(21) Appl. No.: 18/918,276

(22) Filed: Oct. 17, 2024

Related U.S. Application Data
(60) Provisional application No. 63/599,689, filed on Nov. 16, 2023.

(51) Int. Cl. H01L 21/67; C23C 14/48; C23C 14/54; G01N 21/88; G01N 21/958

(52) U.S. Cl. CPC H01L 21/67253; C23C 14/48; C23C 14/54; G01N 21/8806; G01N 21/958; G01N 2021/8845

(57) ABSTRACT

An ion implantation system includes a sensor for monitoring depositions of particles or flakes of other materials. The sensor monitors film thickness on a clear panel from behind the clear panel by emitting light and detecting reflections from the light. The system generates an alert for a buildup thickness. The composition of the film may also be detected by the sensor.

### CROSS-REFERENCE TO RELATED APPLICATIONS

This application claims the benefit of priority to U.S. provisional application 63/599,689, filed on Nov. 16, 2023. The entirety of this prior application is incorporated herein by reference for all purposes.

### FIELD

The present disclosure relates generally to semiconductor manufacturing systems, and more particularly to monitoring depositions on a semiconductor manufacturing system.

### BACKGROUND

In the manufacture of semiconductor devices, ion implantation is used to dope semiconductors with impurities. Ion implantation systems are often utilized to dope a workpiece, such as a semiconductor wafer, with ions from an ion beam, in order to either produce n- or p-type material doping, or to form passivation layers during fabrication of an integrated circuit. Such beam treatment is often used to selectively implant the wafers with a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. When implanting ions into silicon wafers, ions generated from source materials such as antimony, arsenic, or phosphorus, for example, result in an “n-type” extrinsic material wafer, whereas a “p-type” extrinsic material wafer often results from ions generated with source materials such as boron, gallium, or indium. When implanting ions into silicon carbide (SiC) wafers, for example, nitrogen (n-dopant) and aluminum (p-dopant) are conventionally used as ion species.

A typical ion implanter includes an ion source, an ion extraction device, a mass analysis device, with or without a post acceleration section, a beam transport device, and a wafer processing device. The ion source generates ions of desired atomic or molecular dopant species. These ions are extracted from the ion source by the ion extraction device, which are typically a set of electrodes that energize and direct the flow of ions from the ion source, forming an ion beam. Desired ions are separated from the ion beam in the mass analysis device, which is typically a magnetic dipole performing mass dispersion or separation of the extracted ion beam. The beam transport device, which is typically a vacuum system containing a series of focusing and acceleration/deceleration devices, transports the analyzed ion beam to the wafer processing device while maintaining desired properties of the ion beam. Finally, semiconductor wafers or other targets for implantation are transferred into and out of the wafer processing device via a wafer handling system, which may include one or more robotic arms, for placing a wafer to be treated in front of the analyzed ion beam and removing treated wafers from the ion implanter.

For many ion implantation systems, the physical size of the ion beam is smaller than a target workpiece, whereby the ion beam is scanned in one or more directions in order to adequately cover a surface of the target workpiece. Generally, an electrostatic or magnetic based beam scanner scans the ion beam in a fast direction and a mechanical device moves the target workpiece in a slow scan direction in order to provide sufficient coverage of the ion beam across the surface of the workpiece.

Ion implantation systems produce unwanted depositions that may result from breakdowns of the linings in certain chambers and/or stray particles. Ion implantation systems are highly-tuned instruments that require high precision, and, as such, these depositions can hinder or prevent sufficient operation. Some undesired tool behaviors, such as, for example, rising contaminant particle levels or insufficient sealing of surfaces, may be driven by the deposition of material on key parts of the tool.

Preventative maintenance on ion implanters is typically performed in accordance with a predefined schedule to clean these depositions, for example, by cleaning or replacing parts. If preventative maintenance is done sooner than needed, some tool availability is sacrificed. Conversely, if preventative maintenance is delayed too long, the tool may be unavailable for use unexpectedly or poor quality products may result. Either of which can cause production delays and other problems.

### SUMMARY

The present disclosure provides a system and method for monitoring the depositions in the harsh environment of an ion implantation system. In particular, this monitoring system can be used during operation of the ion implantation system. The system can be monitored for depositions and maintenance can be performed when needed instead of according to a predetermined maintenance schedule. This improves uptime of the ion implantation system and can prevent unexpected deterioration in quality of implantations.

Accordingly, the following presents a simplified summary of the disclosure in order to provide a basic understanding of some aspects of the disclosure. This summary is not an extensive overview of the disclosure. It is not intended to identify key or critical elements of the invention nor to delineate the scope of the invention. Its purpose is to present some concepts of the disclosure in a simplified form as a prelude to the more detailed description that is presented later.

In an aspect, this disclosure relates to an ion implantation system, including: an ion source that generates ions and produces an ion beam along a beamline; a mass analyzer positioned downstream of the ion source that generates a magnetic field according to a selected charge-to-mass ratio and an angle adjustment; a workpiece target associated with the beamline; a controller configured to move the ion beam in relation to a workpiece target; and a sensor device embedded in a wall of a chamber of the ion implantation system, the sensor device including a photodetector, a light source, and a clear panel; the clear panel including an outside face and an inside face, the outside face facing the chamber, the inside face facing opposite the chamber; wherein the photodetector is configured to receive reflected light from deposits on the outside face of the clear panel.

In another aspect, this disclosure relates to a deposition sensor device for a semiconductor manufacturing system, the sensor device including: a photodetector, a light source, and a clear panel; the clear panel including an outside face and an inside face, wherein the light source is configured to emit light toward the inside face of the clear panel, and the photodetector is configured to receive reflected light from deposits on the outside face of the clear panel.

In another aspect, the techniques described herein relate to a method for detecting depositions in a semiconductor manufacturing apparatus including: conducting ion implantation, etching, or deposition operations; emitting light towards an inside face of a clear panel, the clear panel having an inside face and an outside face; detecting light reflected from a deposit on an outside face of the clear panel, the deposit resulting from ion implantation operations; processing the detected light reflected from the deposit; and transmitting an alert signal for maintenance to be performed.

The above summary is merely intended to give a brief overview of some features of some embodiments of the present disclosure, and other embodiments may comprise additional and/or different features than the ones mentioned above. In particular, this summary is not to be construed to be limiting the scope of the present application. Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings. Furthermore, the features of the various embodiments and examples described herein may be combined with each other unless specifically noted otherwise.

### BRIEF DESCRIPTION OF THE DRAWINGS

FIG. 1 is a simplified top view illustrating an ion implantation system in accordance with an aspect of the present disclosure.

FIG. 2 is a Scanning Electron Microscope (SEM) image of an example deposition film built up on a test panel with the results of an Energy Dispersive X-Ray Spectroscopy (EDX) analysis.

FIG. 3 is a cross-sectional schematic view of an example of a sensor device mounted in a chamber of an ion implantation system.

FIGS. 4A-4C are cross-sectional schematics of operations of the sensor device of FIG. 3 as the chamber accumulates depositions.

FIG. 5 is a cross-sectional schematic view of an example of a sensor device mounted to a load lock chamber of an ion implantation system.

FIG. 6 is a flowchart of an example method for detecting depositions in an ion implantation system.

FIG. 7 is a data set showing an example set of data from which an alert may be based on.

FIG. 8 shows a top view of a sensor device 800 that was constructed for testing the concepts disclosed herein.

FIG. 9A is a graph showing data gathered by testing a full range of visible and infrared light as reflected to a photodetector that can separate out intensity at each wavelength.

FIG. 9B is a graph showing data gathered from a control example, where the five different LED wavelengths of the sensor device of FIG. 8 were reflected from an uncoated quartz clear panel and measured.

FIG. 9C and FIG. 9D are graphs showing testing data of the sensor device of FIG. 8.

FIG. 10A (500 nm thickness) and FIG. 10B (1000 nm thickness) show the precision of the sensor with consistent readings at different locations on the sample panel.

### DETAILED DESCRIPTION

It would be advantageous to fit certain semiconductor manufacturing systems with a monitoring device to measure and characterize deposition levels and alert operators when preventative maintenance is imminently needed. Semiconductor manufacturing systems, such as, for example, ion implantation systems, include chambers that are under vacuum and are being bombarded by particle streams or other operations during use. There are difficulties in monitoring internal depositions in such systems due to the harsh conditions inside chambers of these systems.

The present disclosure is directed generally toward various apparatuses, systems, and methods associated with implantation of ions into a workpiece or other semiconductor manufacturing processes. More specifically, the present disclosure is directed to a semiconductor manufacturing system with a deposition monitor and method for detecting depositions and alerting when maintenance is needed. Ion implantation systems and other semiconductor manufacturing systems, such as etch (e.g., thin film etch) and deposition (e.g., plasma deposition) semiconductor manufacturing systems, may also incorporate the deposition sensor disclosed herein.

Accordingly, the technology is described with reference to the drawings, wherein like reference numerals may be used to refer to like elements throughout. It is to be understood that the description of these aspects is merely illustrative and that they should not be interpreted in a limiting sense. In the following description, for purposes of explanation, numerous specific details are set forth in order to provide a thorough understanding of the technology described herein. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as exemplary only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components for all embodiments encompassed by this disclosure.

It is also to be understood that in the following description, any direct connection or coupling between functional blocks, devices, components, or other physical or functional units shown in the drawings or described herein could also be implemented by an indirect connection or coupling. Furthermore, it is to be appreciated that functional blocks or units shown in the drawings may be implemented as separate features or components in one embodiment, and may also or alternatively be fully or partially implemented in a common feature or component in another embodiment.

The terms workpiece and workpiece support are used herein with recognition that a workpiece will be utilized in operation, but a workpiece support is used to hold and position the workpiece. Furthermore, ion implantation systems may be produced with workpiece supports that are configured to hold workpieces, but are not typically manufactured or sold with workpieces. Thus, discussion of a workpiece and how the beam or components of the ion implantation systems disclosed herein relate to a workpiece should also be understood to be disclosed in terms of the workpiece support. The term “workpiece target” is used herein to mean either a workpiece if the workpiece is in place on the workpiece support or the location where a workpiece is configured to be held by a workpiece support.

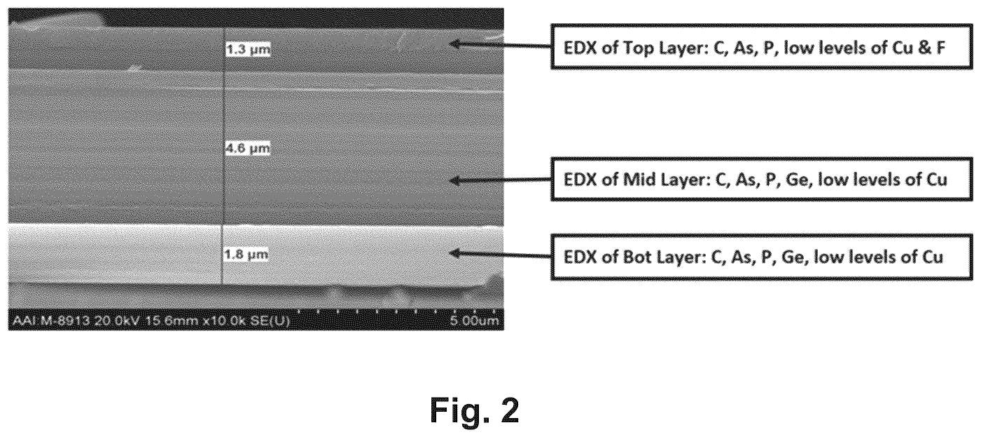

Ion implantation systems, particularly high dose implanters, generate substantial amounts of sputtering from graphite liners, Faraday devices, and apertures in the system. These particles are deposited onto surfaces in the chambers of the system or on the workpiece. These depositions build up in films (see, e.g., FIG. 2 discussed below), and eventually the films will flake or shed off and can land on the workpiece.

Particles of graphite and photoresist materials are likely to constitute the deposition film in the process chamber. Particles of dopants, insulators, and conductors constitute deposition film in the beamline area. Particles of feed gases and reaction byproducts constitute the deposition film near the source. As can be seen, after several months of use, approximately 8 microns of deposition film had built up on the test silicon wafer.

In a maintenance procedure, these surfaces can be cleaned or replaced to prevent such flaking onto the workpiece. The preventative maintenance procedure is time-consuming and the parts to be replaced are expensive. Disclosed herein is a system and method for monitoring depositions in the system and identifying a correct time to conduct the maintenance procedure. This is an improvement over conducting scheduled preventative maintenance, which may be premature or may be too late to prevent flaking onto workpieces. The monitoring device disclosed herein includes a sensor chamber sealed by a clear panel that divides the sensor chamber from a chamber of the ion implantation system, which is typically under vacuum. In an exemplary embodiment, the sensor chamber is not under vacuum thus allowing easier maintenance and cooling of electrical parts and connections. The window is monitored for reflection of light to determine how much deposition, or how thick the coating of the deposited contaminants is.

Ion implantation is a physical process, as opposed to diffusion, which is a chemical process, that is employed in semiconductor apparatus fabrication to selectively implant dopant into a semiconductor workpiece and/or wafer material. Thus, the act of implanting does not rely on a chemical interaction between a dopant and the semiconductor material. For ion implantation, dopant atoms/molecules are ionized and isolated, sometimes accelerated or decelerated, formed into a beam, and swept across a workpiece or wafer. The dopant ions physically bombard the workpiece, enter the surface, and typically come to rest below the workpiece surface in the crystalline lattice structure thereof. The ion beam is unimpeded by any sort of window or glass. Thus, any analysis and monitoring of the deposition on the interior walls of the ion implantation system cannot be done by analysis of the beam or the path of the beam.

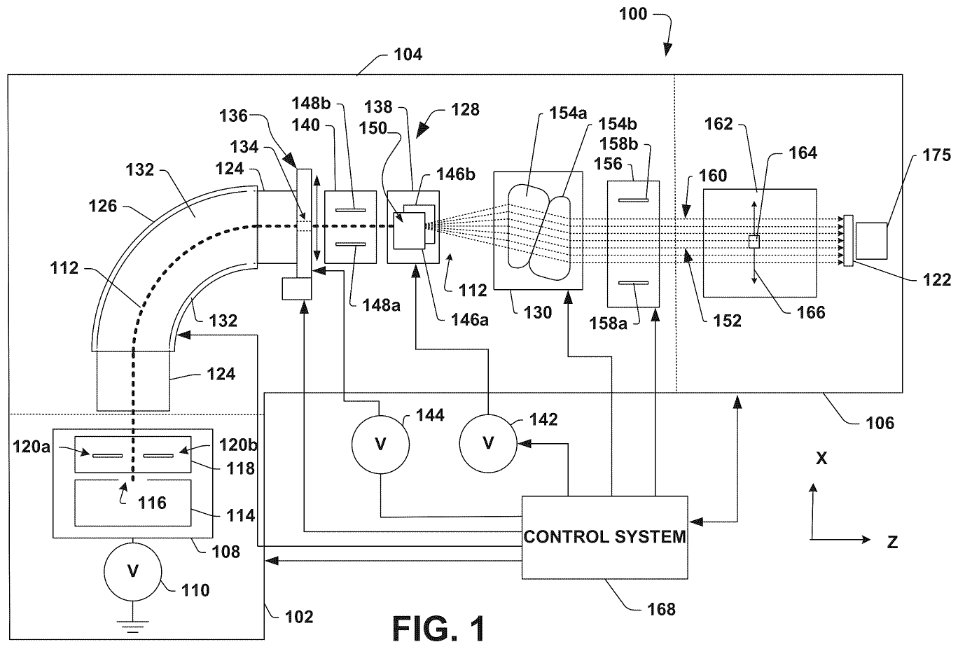

Referring now to the Figures, FIG. 1 is a schematic of an example ion implantation system 100 in accordance with an aspect of the present disclosure. The system 100 is presented for context and illustrative purposes, and it is appreciated that aspects of the invention are not limited to the described ion implantation system and that other suitable ion implantation systems of varied configurations can also be employed.

The system 100 has a terminal 102, a beamline assembly 104, and an end station 106. The terminal 102 includes an ion source 108 powered by a high voltage power supply 110 that produces and directs an ion beam 112 having a selected species to the beamline assembly 104. The ion source 108 generates charged ions that are extracted and formed into the ion beam 112, which is directed along a beam path in the beamline assembly 104 to the end station 106.

To generate the ions, a gas of a dopant material (not shown) to be ionized is located within an ion generation chamber 114 of the ion source 108. The dopant gas can, for example, be fed into the ion generation chamber 114 from a gas source (not shown). In addition to power supply 110, it will be appreciated that one or more suitable mechanisms (not shown) can be used to excite free electrons within the ion generation chamber 114, such as, for example, RF or microwave excitation sources, electron beam injection sources, electromagnetic sources and/or a cathode which creates an arc discharge within the chamber. The excited electrons collide with the dopant gas molecules and ions are generated thereby. Typically, positive ions are generated although the disclosure herein is applicable to systems wherein negative ions are generated as well.

The ions are controllably extracted through a slit 116 in the ion generation chamber 114 by an ion extraction assembly 118, in this example. The ion extraction assembly 118 comprises a plurality of extraction and/or suppression electrodes 120a, 120b. The ion extraction assembly 118 can include, for example, a separate extraction power supply (not shown) to bias the extraction and/or suppression electrodes 120a, 120b to accelerate the ions from the ion generation chamber 114. It can be appreciated that since the ion beam 112 comprises like-charged particles, the beam may have a tendency to expand radially outwardly as the like charged particles repel one another. It can also be appreciated that beam expansion can be exacerbated in low energy, high current (high perveance) beams where many like charged particles (e.g., high current) are moving in the same direction relatively slowly (e.g., low energy) such that there is an abundance of repulsive forces among the particles, but little particle momentum to keep the particles moving in the direction of the beam path. Accordingly, the ion extraction assembly 118 is generally configured so that the beam is extracted at a high energy so that the beam does not expand unduly (e.g., so that the particles have sufficient momentum to overcome repulsive forces that can lead to beam expansion). Moreover, the beam 112, in this example, is generally transferred at a relatively high energy throughout the system 100 and is reduced just before a workpiece 122 held on a workpiece support 175 positioned in the end station 106 to promote beam containment. The workpiece target in this case is where workpiece 122 is located or where it is configured to be located on the workpiece support 175.

In the example of FIG. 1, the beamline assembly 104 has a beamguide 124, a mass analyzer 126, a scanning system 128, and a parallelizer and/or corrector component 130 (referred to generally as a parallelizer). The mass analyzer 126 performs mass analysis and angle correction/adjustment on the ion beam 112. The mass analyzer 126, in this example, is formed at about a ninety-degree angle and comprises one or more magnets (not shown) that serve to establish a (dipole) magnetic field therein. As the beam 112 enters the mass analyzer 126, it is correspondingly bent by the magnetic field such that ions of an inappropriate charge-to-mass ratio are rejected. More particularly, ions having too great or too small a charge-to-mass ratio are deflected into side walls 132 of the mass analyzer 126. In this manner, the mass analyzer 126 mainly allows those ions in the beam 112 which have the desired charge-to-mass ratio to pass there-through and exit through a resolving aperture 134 of a mass resolving aperture assembly 136, details of which will be discussed further infra.

The mass analyzer 126 can perform angle corrections on the ion beam 112 by controlling or adjusting an amplitude of the magnetic dipole field. This adjustment of the magnetic field causes selected ions having the desired/selected charge-to-mass ratio to travel along a different or altered path. As a result, the resolving aperture 134 can be adjusted according to the altered path. In one example, the mass resolving aperture assembly 136 is movable about an x direction (e.g., a direction transverse to the ion beam 112) so as to accommodate altered paths through the resolving aperture 134.

It will be appreciated that collisions of the ion beam 112 with other particles in the system 100 can degrade beam integrity. Accordingly, one or more pumps (not shown) may be included to evacuate, at least, the beamguide 124 and mass analyzer 126.

The scanning system 128 in the illustrated example includes a magnetic scanning element 138 and a focusing and steering element 140. Respective power supplies 142, 144 are operatively coupled to the magnetic scanning element 138 and the focusing and steering element 140 and, more particularly, to respective electromagnets 146a, 146b and electrodes 148a, 148b located therein.

The focusing and steering element 140 receives the mass analyzed ion beam 112 having a relatively narrow profile (e.g., a “pencil” beam). A voltage applied by the power supply 144 to the electrodes 148a and 148b operates to focus and steer the beam to a scan vertex 150 of the magnetic scanning element 138. A voltage waveform applied by the power supply 142 (which could be the same supply as 144) to the electromagnets 146a and 146b then scans the beam 112 back and forth, in this example, therein defining a scanned ion beam 152 (sometimes called a “ribbon beam”). It will be appreciated that the scan vertex 150 can be defined as the point in the optical path from which each beamlet or scanned part of the ion beam 112 appears to originate after having been scanned by the magnetic scanning element 138.

The scanned ion beam 112 is then passed through the parallelizer 130, which comprises two dipole magnets 154a, 154b in the illustrated example. The two dipole magnets 154a, 154b, for example, are substantially trapezoidal and are oriented to mirror one another to cause the beam 112 to bend into a substantially s-shape. Stated another way, the two dipole magnets 154a, 154b have equal angles and radii and opposite directions of curvature.

The parallelizer 130 causes the scanned ion beam 112 to alter its path such that the ion beam travels parallel to a beam axis regardless of the scan angle. As a result, the implantation angle is relatively uniform across the workpiece 122.

One or more deceleration stages 156 are located downstream of the parallelizer 130 in this example. Up to this point in the system 100, the ion beam 112 is generally transported at a relatively high energy level to mitigate the propensity for beam expansion, which can be particularly high where beam density is elevated such as at the scan vertex 150, for example. The one or more deceleration stages 156, for example, comprise one or more electrodes 158a, 158b operable to decelerate the beam 112. The one or more electrodes 158a, 158b are typically apertures thru which the ion beam 112 travels, and may be drawn as straight lines in FIG. 1.

Nevertheless, it will be appreciated that while two electrodes 120a and 120b, electromagnets 146a and 146b, electrodes 148a and 148b and 158a and 158b are respectively illustrated in the exemplary ion extraction assembly 118, the magnetic scanning element 138, focusing and steering element 140, and deceleration stage 156, these elements may respectively comprise any suitable number of electrodes arranged and biased to accelerate and/or decelerate ions, as well as to focus, bend, deflect, converge, diverge, scan, parallelize and/or decontaminate the ion beam 112, such as is provided in U.S. Pat. No. 6,777,696 to Rathmell, et al., the entirety of which is hereby incorporated herein by reference. Additionally, the focusing and steering element 140 may comprise electrostatic deflection plates (e.g., one or more pairs thereof), as well as an Einzel lens, quadrupoles and/or other focusing elements to focus the ion beam.

The end station 106 then receives the ion beam 112 which is directed toward the workpiece 122. It is appreciated that different types of end stations 106 may be employed in the ion implantation system 100. For example, a “batch” type end station can simultaneously support multiple workpieces 122 on a rotating workpiece support structure, wherein the workpieces are rotated through a beam path 160 (also called a beamline) of the ion beam 112 until all the workpieces are completely implanted. A “serial” type end station, on the other hand, supports a single workpiece 122 along the beam path 160 for implantation, wherein multiple workpieces are implanted one at a time in serial fashion, with each workpiece being completely implanted before implantation of the next workpiece begins. In hybrid systems, the workpiece 122 may be mechanically translated in a first direction (the y-direction or so-called “slow scan” direction) while the ion beam 112 is scanned in a second direction (the x-direction or so-called “fast scan” direction) to impart the beam 112 over the entire workpiece 122.

In an example, a workpiece support 175 is coupled to a mechanical beam-to-workpiece translation system that moves the workpiece 122 in relation to the beam 112 in either an x-direction, a y-direction, or x-and y-direction. This is an alternative to a beam-to-workpiece translation system that scans the beam 112 across one or more dimensions of the workpiece 122. A hybrid system may also be utilized as described above. For purposes of the presently disclosed technology, whether the beam 112 is scanned or the workpiece 122 is moved, the speed and positioning of the beam 112 in relation to the workpiece 122 (the beam-to-workpiece speed and position) is of interest.

The end station 106 in the illustrated example is a “serial” type end station that supports the single workpiece 122 along the beam path 160 for implantation. A dosimetry system 162, for example, is included in the end station 106 near the location of the workpiece 122 for measurements of the ion beam 112 (e.g., measurements may be performed prior to implantation operations). During calibration, the beam 112 passes through dosimetry system 162. The dosimetry system 162, for example, includes one or more profilers 164 that may continuously traverse a profiler path 166, thereby measuring the profile of the scanned ion beam 152.

The one or more profilers 164, for example, may comprise a current density sensor, such as a Faraday cup, that measures the current density of the scanned ion beam 152, where current density is a function of the angle of implantation (e.g., the relative orientation between the ion beam and the mechanical surface of the workpiece 122 and/or the relative orientation between the ion beam and the crystalline lattice structure of the workpiece). The current density sensor, for example, moves in a generally orthogonal fashion relative to the scanned ion beam 152 and thus typically traverses the width of the scanned ion beam. The dosimetry system 162, in one example, measures both beam density distribution and angular distribution.

A control system 168 (also called a controller) is further provided to control, communicate with, and/or adjust the ion source 108, the mass analyzer 126, the mass resolving aperture assembly 136, the magnetic scanning element 138, the parallelizer 130, and the dosimetry system 162. The control system 168 may comprise a computer, microprocessor, etc., and may be operable to take measurement values of characteristics of the ion beam 112 and adjust parameters accordingly. The control system 168 can be coupled to the terminal 102 from which the ion beam 112 is generated, as well as the mass analyzer 126 of the beamline assembly 104, the magnetic scanning element 138 (e.g., via power supply 142), the focusing and steering element 140 (e.g., via power supply 144), and the deceleration stage 154. Accordingly, any of these elements can be adjusted by the control system 168 to facilitate desired ion implantation.

The strength and orientation of magnetic field(s) generated in the mass analyzer 126 can be adjusted, such as by regulating the amount of electrical current running through field windings therein to alter the charge to mass ratio of the beam, for example. The angle of implantation can be controlled by adjusting the strength or amplitude of the magnetic field(s) generated in the mass analyzer 126 in coordination with the mass resolving aperture assembly 136. The control system 168 can adjust the magnetic field(s) of the mass analyzer 126 and position of the resolving aperture 134 according to measurement data from, in this example, the profiler 164. The control system 168 can verify the adjustments via additional measurement data and perform additional adjustments via the mass analyzer 126 and the resolving aperture 134, if necessary.

While the sensor device disclosed herein is primarily described for use in ion implantation systems, it can also be used in other semiconductor processing equipment. Other semiconductor manufacturing systems include etch and deposition type semiconductor manufacturing systems. In particular, the sensor device is for use in semiconductor processing chambers that are under vacuum and produce films or other depositions with extended use.

The sensor device disclosed herein can be coupled to an instrument chamber, such as an outer chamber of the ion implantation system 100. The chamber can be configured to be under vacuum, and be under vacuum in operation. For example, the sensor device can be coupled to the terminal 102, the beamline assembly 104, and/or the end station 106. The dosimetry system 162 within the end station 106 is a particular area of interest for deposition monitoring. Sputtered particles or flakes of deposition can be detected in this area where the profiler 164 measures current density just before the beam impacts the workpiece 122.

In addition, the sensor device could be coupled to the ion source 108 chamber. Deposition build-up can be caused by sub-components of the ion source 108, for example, the ion generation chamber 114 and the ion extraction assembly 118. But monitoring is best done in a chamber on an outside wall of the ion source 108 chamber, so the components do not need to be under vacuum.

Monitoring the side walls 132 of the mass analyzer 126 may be useful in eliminating particles flaking off and creating problems downstream. In an example, significant problems can be detected by monitoring for abrupt changes in these areas, such as the beam impacting and etching the side walls 132.

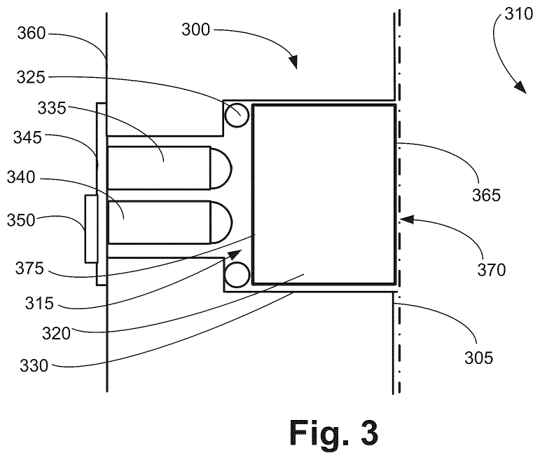

FIG. 3 is a cross-sectional schematic view of an exemplary sensor device 300. The sensor device 300 is embedded in an opening 315 in a side wall 305 of a chamber 310 of the ion implantation system. The opening 315 can be formed, for example, by drilling a cylindrical hole in the side wall 305 of the chamber 310. The chamber 310 can be other geometries as well, such as cubic or frustoconical. Example depths and diameters of the opening 315 may be, for example, 0.5 cm to 20 cm, such as, 1 cm to 15 cm, or 2 cm to 8 cm for either the depth or the diameter.

A clear panel 320 is disposed on a side of the chamber 310. The clear panel 320 allows light to pass through it with high transmittance, for example, 80% or more at 90 degrees incidence, such as, 90% to 99%, or 93% to 98%. The clear panel 320 should have a thickness sufficient to allow the reflectance to be detected as discussed below. This thickness may be, for example, 1 cm, or 0.25 to 5 inches, 0.5 to 3 inches, or 0.75 to 1.5 inches. The clear panel 320 may be made of glass or clear polymers. For example, the clear panel 320 may comprise one or more of quartz, silica, soda lime, borosilicate, aluminum, lead, soda, barium oxide, thorium oxide, lanthanum oxide, cerium oxide, fluorine, acrylic, polycarbonate, or polyethylene terephthalate.

In an example, an outside face 365 of the clear panel 320 is substantially flush with the side wall 305 of the chamber 310. A deposition film 370 is depicted on the outside face 365 of the clear panel 320. The clear panel 320 is backed by a seal 325. The seal can be a rubber O-ring or some other elastomeric or metal material in a suitable geometry that effectively forms a seal against a vacuum. The seal 325 seals the inside face 375 of the clear panel 320 against the outside face 365 of the clear panel 320. The seal 325 touches an inner wall 330 of the chamber 310 and an inside face 375 of the clear panel 320. In other examples, the seal 325 could touch side faces of the clear panel 320 and the side wall 305 of the chamber 310. The clear panel 320 is held in place in the chamber 310, for example, by having a sealing plate bolted to the chamber 310 as is done with other ports to the chamber 310. Alternatively, the clear panel 320 could be held in place in the chamber 310 by being adhered to the side wall 305 of the chamber 310. Other mechanisms for retaining the clear panel 320 in the chamber 310 can also be utilized, for example, a retainer ring could be placed around the outside face 365 of the clear panel 320 and be adhered or otherwise fastened to the side wall 305 of the chamber 310.

In an embodiment, the chamber 310 is under vacuum during operation. The side wall 305 may be made of a suitable material, such as aluminum, or another metal that is sufficiently rigid for withstanding the vacuum of the chamber 310. The sensor device 300 can be embedded in various chambers in the ion implantation system as mentioned above.

Behind the clear panel 320 is a photodetector 335 and a light source 340 in a sensor chamber. The light source 340, may, for example, be an LED array comprising multiple-colored LEDs, i.e., LEDs emitting light at different wavelengths. The wavelengths may, for example, correspond to one or more of red, blue, and green in the visible light spectrum. Wavelengths ranging from 620 to 750 nm (red), 450 to 495 nm (blue), 495 to 570 nm (green) may be used. The light source 340 may also or instead emit light in the infrared range, e.g., 780 to 1500 nm, such as 790 to 900 nm. In an example, the light source 340 comprises multiple LEDs in an array, one each dedicated to red, green, blue, and infrared light. Incandescent or laser light could also be used.

The photodetector 335, may, for example, be a photodiode, such as a p-n, p-i-n, or avalanche photodiode, or a metal semiconductor (MSM) photodetector. In an example, the photodetector is capable of detecting multiple colors/wavelengths, including, for example, red, blue, green, and infrared. In some examples, multiple photodetectors 335 are present to account for different wavelengths, for example, one photodetector 335 for infrared and one photodetector 335 for visible light. In any event, the photodetector 335 should be capable of detecting the wavelength emitted from the light source 340. In this example, the photodetector 335 is a wide response detector, for example, detecting light in a half-sphere, or a 50 to 100% of a half sphere, or 75 to 90% of a half-sphere.

In another embodiment, the photodetector 335 can be located outside the opening 315 and completely outside any walls of the chamber 310. A fiberoptic cable could run from the opening 315, e.g., where the photodetector 335 is depicted in the Figures, to a photodetector 335 located outside the chamber 310. A fiberoptic cable could also transmit light and take the place of the light source 340 in the Figures. The other end of the fiberoptic cable would be coupled to a light source outside the opening 315 and completely outside any walls of the chamber 310.

In the example sensor device 300 of FIG. 3, the photodetector 335 and light source 340 are coupled to (e.g., mounted on) a backing panel 345, which is attached to an exterior surface 360 of the chamber 310.

In the example of FIG. 3 the photodetector 335, and in some examples, the light source 340 are in communication with a local processor 350. In other examples, the processor could be remote and coupled via electrical wiring.

The processor 350 processes the signal received from the photodetector 335 and communicates information to a user, for example, by providing a simplified signal to a computing device, or even sending a report to a display screen directly. The report or alert that is communicated through the computing device or display screen directly may indicate that no maintenance is needed, maintenance is needed within e.g., 6 months, 3 months, 1 month, or immediately. Alerts may also indicate that a large change in reflectivity has occurred in a short amount of time—thus indicating a significant problem. The processor 350 may also control the light source 340, controlling it to turn off and on, and in some examples regularly pulsing the light emission. Pulsing the light emission can provide better signals and data.

The photodetector 335 and light source 340 should both be oriented or configured (e.g., with fiber optics) so that the emitted light from the photodetector 335 will impact the outside face 365 of the clear panel 320 and at least some of the reflected light from deposits on the outside face 365 will be detected by the photodetector 335. In the example of FIG. 3, the photodetector 335 and light source 340 are both oriented in the same direction and are immediately adjacent to each other. In other examples, the photodetector 335 and light source 340 could be oriented in different directions, but ordinarily care should be taken so that light rays emitted directly from the light source are not bombarding the photodetector 335 and overwhelming any signal from the reflected light rays. In an example, a light guard could be set up between the photodetector 335 and light source 340 to prevent the light rays emitted directly from the light source from being detected by the photodetector 335.

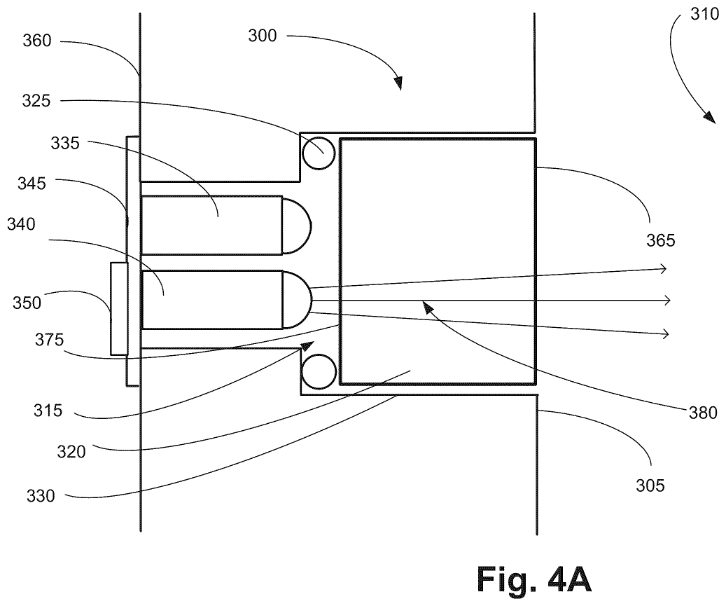

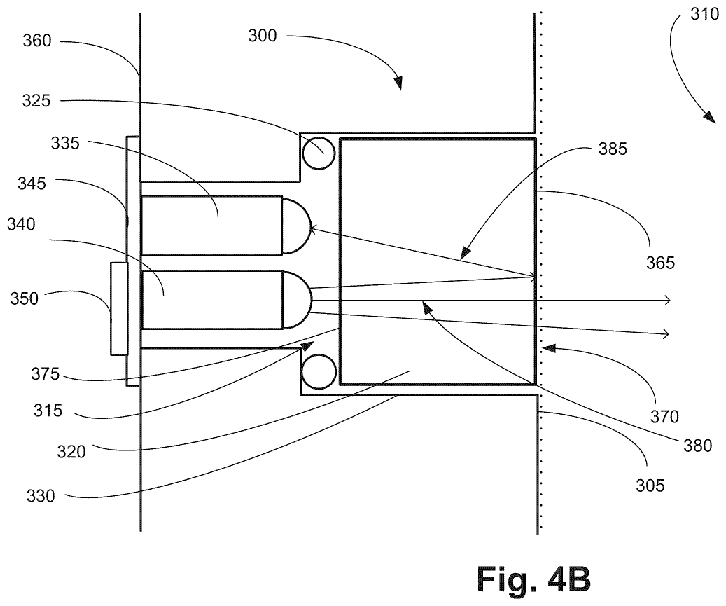

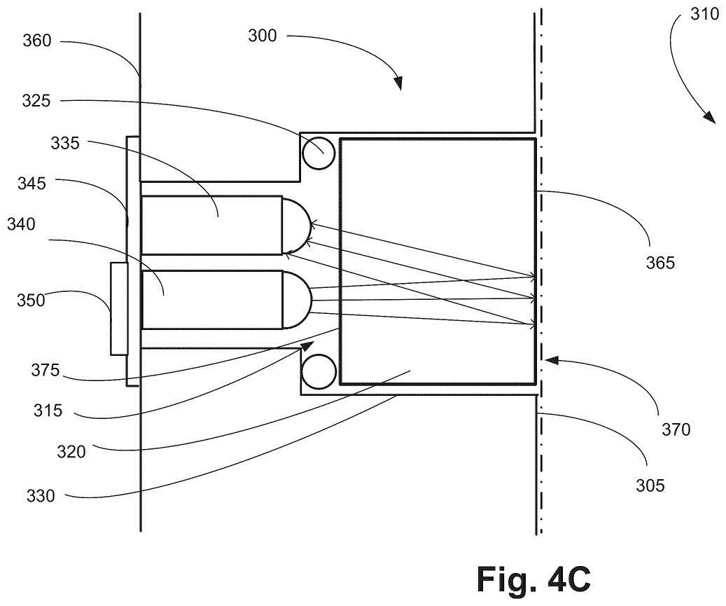

FIGS. 4A-4C depict operations of the sensor device 300 as the chamber 310 accumulates depositions.

In FIG. 4A the chamber 310 is new or just cleaned and there is no deposition film 370. Light rays 380 are emitted from the light source 340. The light rays 380 travel through the clear panel 320 and into the chamber 310 without any substantial reflection to be detected by the photodetector 335.

In FIG. 4B the chamber 310 has been in use for some time, e.g., 0.5 to 2 months, and is accumulating deposits of a deposition film 370. The light rays 380 are now hitting the deposits on the outside face 365 of the clear panel 320 and some reflected light rays 385 are reflecting back towards the photodetector 335. This illustrates a situation where there is some deposition, but not enough to signal a need for maintenance cleaning or replacement.

In FIG. 4C the chamber 310 has been in use for more time, e.g., 3 to 12 months, and is continuing to accumulate deposits of the deposition film 370 on the outside face of the clear panel 320. More light rays 380 are now hitting the deposits on the outside face 365 of the clear panel 320 and more reflected light rays 385 are reflecting back towards the photodetector 335. This illustrates a situation where there is significant deposition that is enough to signal a need for maintenance cleaning or replacement.

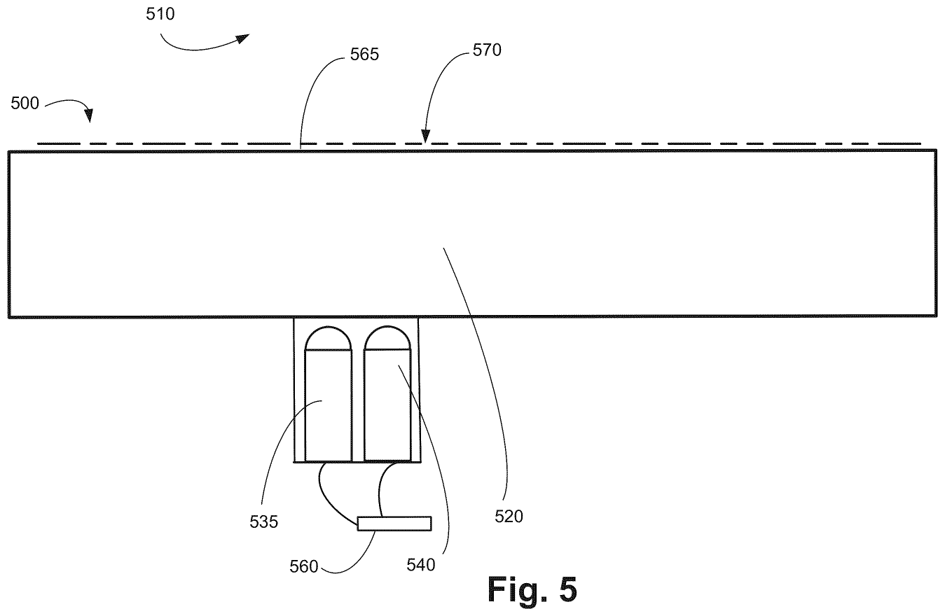

In another example, shown in FIG. 5, a sensor device 500 is used in a load lock chamber 510. The load lock chamber 510 is a preparatory chamber for depressurizing the atmosphere around a workpiece prior to it being loaded into a process chamber (or terminal) where implantation operations occur. There is no ion beam operating in this chamber 510. The deposits that occur in this chamber 510 are typically silicon dust particles that enter the chamber as gates are opened and pressure differences create turbulence.

In FIG. 5, a photodetector 535 and light source 540 pair are set side-by-side underneath a clear panel floor 520 of the load lock chamber 510. The photodetector 535 and light source 540 are coupled to a processor 560, which can be local or remote. The processor 560 may provide simplified signals to a main processor for the ion implantation device, and/or control the emitting, sensing, and alerting process as discussed above.

In an alternative approach, instead of detecting light reflected back from depositions on the outside of a clear panel with a photodetector located behind a clear panel, reflectance from depositions could also be detected from the top of the deposition as it reflects light inside the chamber. For example, the light source would project light through the chamber to a target on a side of the chamber and a photodetector would detect the reflected light on another adjacent side of the chamber. In this case a clean sample chamber would reflect a higher amount of light than a chamber with deposits on it. The deposits would cause the light to be less reflective. For example, the light source would shine light from an adjacent side of the chamber, to a target area on the side of the chamber, and a photodetector on another adjacent side (an opposite side of the chamber from the light source) would be configured to detect the reflected light.

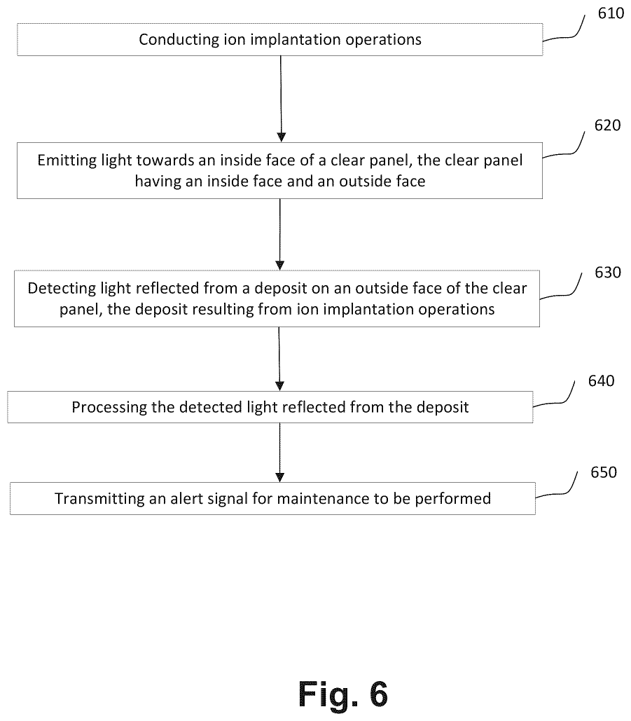

In reference now to FIG. 6, the methodology associated with the sensor device used in the ion implantation system will be further described. FIG. 6 is a flowchart of an example method for detecting depositions in an ion implantation system.

At operation 610, after assembly of the sensor device in a chamber of the ion implantation system. Ion implantation operations are conducted, such as those described above in a system such as shown in FIG. 1. Typically, operations can continue without maintenance for several months.

At operation 620, light is emitted towards an inside face of a clear panel, the clear panel having an inside face and an outside face. The clear panel can be either a panel mounted flush with the side of a process chamber, such as in FIG. 3, or on a glass floor, such as shown in FIG. 5. The light may be emitted by an LED array as discussed above. The light may be multi-colored and/or infrared.

At operation 630, light is detected that is reflected from a deposit on an outside face of the clear panel, the deposit resulting from ion implantation operations. Prior to substantial operations of the ion implantation system either initially or after maintenance all or high amounts of emitted light from the sensor will be transmitted through the clear panel and not be reflected back for detection. After some time, e.g., a few weeks or months of operation, the deposits will cause a film to build on the clear panel. More and more light will be reflected back to a photodetector for detection.

FIG. 2 is an image generated by energy dispersive X-ray spectroscopy of a layered deposition on a silicon test wafer place on a graphite liner of an ion implantation system and then removed and examined for depositions. As can be seen in FIG. 2, different layers show different types of depositions.

Using Energy Dispersive X-Ray Spectroscopy (EDX) allows for the detection of different chemical species in the depositions. FIG. 2 shows how deposits that differ in molecular constitution are differentiated by the brightness of the layers in the SEM image. For example, chamber liners are often made of graphite and Faraday devices also typically include graphite. This will produce a spectra rich in carbon. Ion sources and dopants may produce fluorine, boron, arsenic, phosphorous, and germanium deposits. Using different wavelengths to reflect off the deposition film provides a spectrum of reflected light that provides more information as to which species are in the deposits.

Depending on the shielding, and the amount of light coming from inside the system itself, there may be a high level of background light entering the detector. One method of calibrating the system for this, is to pulse the light source and record a baseline signal for when the light source is off and a separate average for when the light source is pulsed on. These averages can be taken over a time period, such as, for example, 1 hour to 1 month, or 1 day to 4 weeks. In this way, a calibration for a baseline condition can be made. By subtracting the averaged detected light when the light source is off from the averaged detected light from when the light source is on, an accurate calibrated signal can be determined for the reflected light from the light source alone.

At operation 640, a processor is used to analyze the detected light reflected from the deposit. If the light is of different wavelengths, this enables the operator to have more information about the origin of the deposits. Machine learning can be used to enable the processor to identify certain spectra as being indicative of a breakdown or contamination in a particular area of the ion implantation system. For example, spectra data records can be kept and correlated to background and known points of failure. The gathered spectra data can then be analyzed in real time by comparing it to the previously stored and compiled data compiled with machine learning. The results of the analysis can be provided to be displayed to the operator.

Understanding the composition of the deposits may allow the maintenance to be focused on a particular area of the ion implantation system, and lessen the cost and downtime of the system. When maintenance actions are performed on the system, actions taken and/or conditions (such as deposition film depth and composition) empirically determined, these can be input and stored as further training examples for the machine learning.

At operation 650, an alert signal is transmitted for maintenance to be performed. This can be transmitted by the processor to a display, such as a monitor screen. The alert may be an alert that maintenance is needed within e.g., 6 months, 3 months, 1 month, or immediately. Alerts may also indicate that a large change in reflectivity has occurred in a short amount of time—thus indicating a significant problem. In addition, a more detailed report regarding raw data on the wavelengths of the reflected light spectra, or processed data aided by machine learning indicating the composition of the deposition film may also be provided.

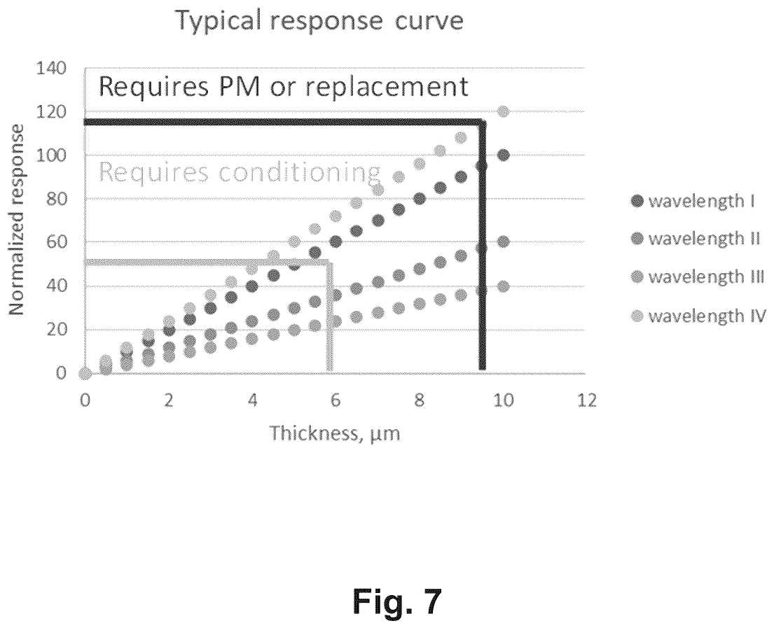

FIG. 7 is a data set on which an alert may be based. The example data set illustrated in FIG. 7 may be a part of the report provided to the operator. For example, one dot for each wavelength may be shown as a picture of the deposition occurring at a point in time. In another example, the history of the deposition film accruing may be shown with multiple dots for each wavelength. This data can also be used to predict when maintenance will need to happen by fitting a curve to the data and extrapolating how much time it will take to reach a limit for maintenance to occur.

### EXAMPLES

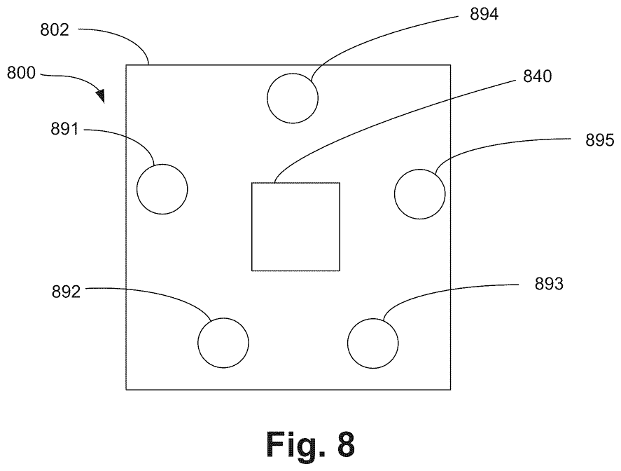

FIG. 8 shows a top view of a sensor device 800 that was constructed for testing the concepts disclosed above. The sensor device 800 included a photodiode 840 in the center of a fixture 802. Five LEDs 891-895 emitting at different wavelengths are arranged around the photodiode 840. A first LED 891 emits light at 470 nm (blue). A second LED 892 emits light at 525 nm (green). A third LED 893 emits light at 630 nm (red). A fourth LED 894 emits light at 850 nm (infrared). A fifth LED 895 emits light at 780 nm (infrared). A clear panel was placed over the LEDs 891-895 and the photodiode 835 to reflect the light back to the photodiode 835. To maximize the response from the photodiode 835 each LED 891-895 was oriented at an angle towards the center of the clear panel in an attempt to approximate the best angle for the photodiode to receive the reflected light.

The sensor device 800 was operated and tested with test panels having DLC (diamond-like coating) films to simulate deposition film thicknesses of 500 nm, 750 nm, and 1000 nm. Changes in the responses of different wavelengths were observed with the different test panels.

### Example 1

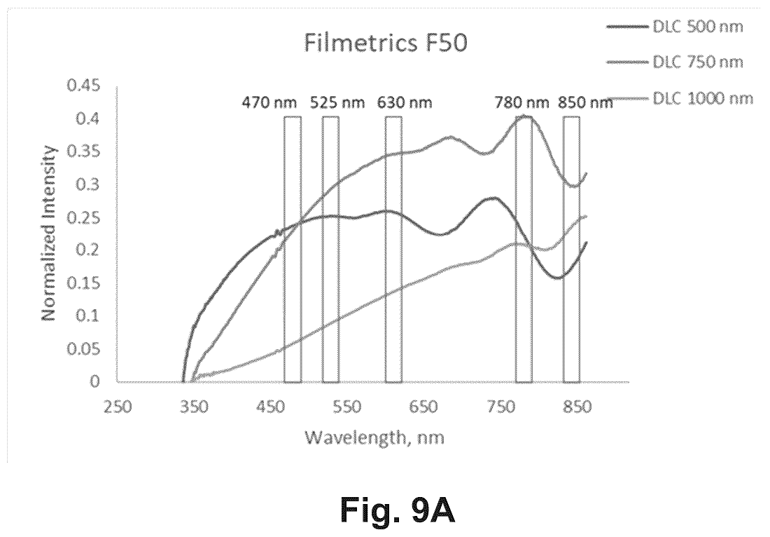

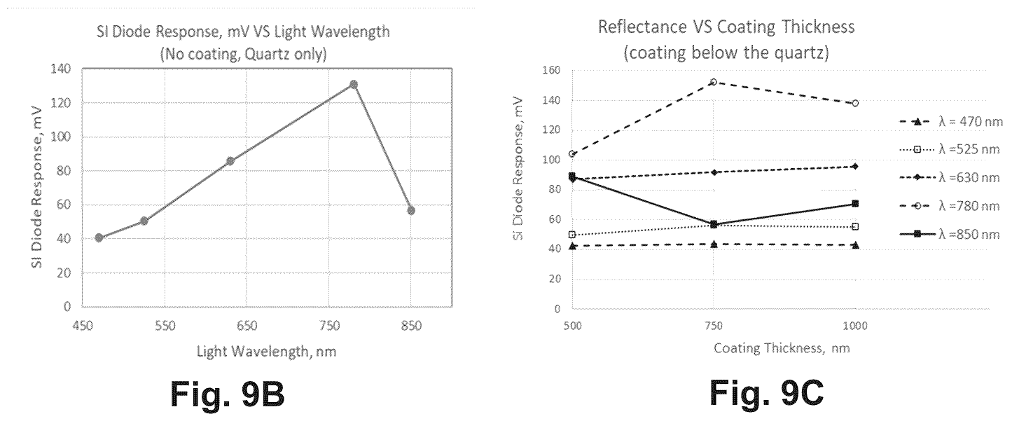

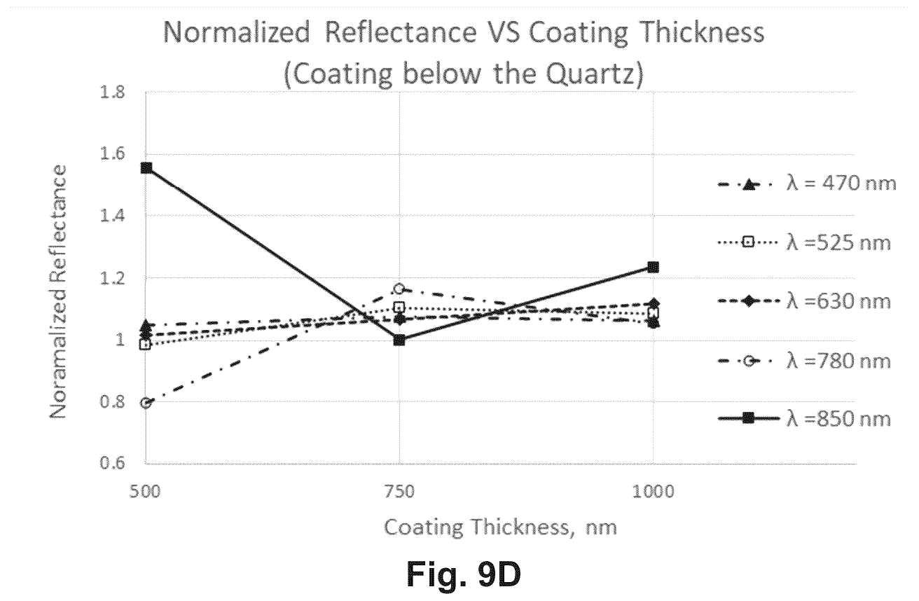

FIG. 9A is a graph showing data gathered by testing a full range of visible and infrared wavelengths as reflects to a photodetector that can separate out intensity at each wavelength. The results demonstrated differences in reflectance and changes in the responses at different wavelengths for the same thickness. The rectangles on the FIG. 9A graph indicate the five wavelengths to be tested with the device of FIG. 8. This indicates that the simpler, less expensive, device using only 5 different wavelengths should still provide a large amount of data on the deposition layers, enabling the user to determine thickness and perhaps compositional differences.

### Example 2

FIG. 9B is a graph showing a control example, where the five different LED wavelengths of the sensor device of FIG. 8 were reflected from an uncoated quartz clear panel and measured. This was done to aid in calibrating and normalizing the sensor.

### Example 3

FIG. 9C and FIG. 9D are graphs showing testing data of the sensor device of FIG. 8. The five different LEDs wavelengths of the sensor device of FIG. 8 were reflected from three different thicknesses of coated test panels set behind a quartz clear panel and measured. The results indicated that reflectance of the 5 wavelengths could be used to distinguish coating thickness. For the same wavelength, different thicknesses had different reflectance. For the same thickness, different wavelengths had different reflectance.

### Example 4

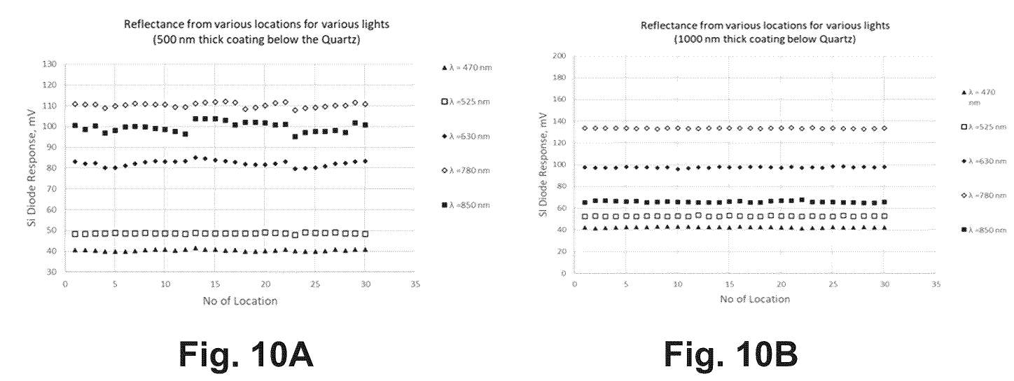

Example 3 was repeated several times at different locations on two of the coated sample panel and the results were very consistent showing high precision of the sensor device. FIGS. 10A (500 nm thickness) and 10B (1000 nm thickness) show the repeatability of the sensor's performance at different locations on the sample panel.

It was determined that coating thickness was almost the same over all the tested locations of the coated quartz sample area (less than 1% variation). There was only ±1 mV fluctuation in terms of signal to noise response. This is statistically surprisingly consistent data indicating that this approach will be successful in an actual installation in an ion implantation system.

Although the disclosure has been shown and described with respect to a certain applications and implementations, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including any reference to a “means”) used to describe such components are intended to correspond, unless otherwise indicated, to any component which performs the specified function of the described component (i.e., that is functionally equivalent), even though not structurally equivalent to the disclosed structure, which performs the function in the herein illustrated exemplary implementations of the disclosure.

In addition, while a particular feature of the disclosure may have been disclosed with respect to only one of several implementations, such feature may be combined with one or more other features of the other implementations as may be desired and advantageous for any given or particular application. Furthermore, to the extent that the terms “includes,” “including,” “has,” “having,” and variants thereof are used in either the detailed description or the claims, these terms are intended to be inclusive in a manner similar to the term “comprising.”

What is claimed is:

1. An ion implantation system, comprising:
an ion source that generates ions and produces an ion beam along a beamline;
a mass analyzer positioned downstream of the ion source that generates a magnetic field according to a selected charge-to-mass ratio and an angle adjustment;
a workpiece target associated with the beamline;
a controller configured to move the ion beam in relation to a workpiece target; and
a sensor device coupled to a chamber of the ion implantation system, the sensor device comprising a photodetector, a light source, and a clear panel;
the clear panel comprising an outside face and an inside face, the outside face facing the chamber, the inside face facing opposite the chamber;
wherein the photodetector is configured to receive reflected light from deposits on the outside face of the clear panel.

2. The ion implantation system of claim 1, wherein the light source emits multiple wavelengths of light.

3. The ion implantation system of claim 1, further comprising a processor that causes the light source to pulse light.

4. The ion implantation system of claim 1, further comprising a processor that receives input signals from the photodetector, processes the input signals to a simplified signal, and transmits the simplified signal to a main processer for the ion implantation system.

5. The ion implantation system of claim 1, further comprising a display screen that is configured to transmit an alert relating to a maintenance event based on signals from the photodetector.

6. The ion implantation system of claim 1, wherein the light source comprises LEDs configured to transmit at wavelengths corresponding to red, green, and blue light.

7. The ion implantation system of claim 1, wherein the light source comprises an LED configured to transmit at an infrared wavelength.

8. The ion implantation system of claim 1, wherein the chamber is selected from a load lock chamber, a dosimetry system chamber, ion source chamber, and a mass analyzer chamber.

9. The ion implantation system of claim 1, wherein the chamber is configured to be under vacuum during operation.

10. A deposition sensor device for a semiconductor manufacturing system, the sensor device comprising:
a photodetector, a light source, and a clear panel;
the clear panel comprising an outside face and an inside face,
wherein the light source is configured to emit light toward the inside face of the clear panel, and the photodetector is configured to receive reflected light from deposits on the outside face of the clear panel.

11. The deposition sensor device of claim 10, wherein the photodetector and light source are coupled to a backing plate and the inside face of the clear panel is sealed against the outside face of the clear panel.

12. The deposition sensor device of claim 10, wherein the light source comprises LEDs configured to transmit at wavelengths corresponding to red, green, and blue light.

13. The deposition sensor device of claim 10, wherein the light source comprises an LED configured to transmit at an infrared wavelength.

14. The deposition sensor device of claim 10, further comprising a processor that receives input signals from the photodetector, processes the input signals to a simplified signal, and transmits the simplified signal to a main processer for the semiconductor manufacturing system.

15. A method for detecting depositions in a semiconductor manufacturing apparatus comprising:
conducting ion implantation, etching, or deposition operations;
emitting light towards an inside face of a clear panel, the clear panel having an inside face and an outside face;
detecting light reflected from a deposit on an outside face of the clear panel, the deposit resulting from ion implantation operations;
processing the detected light reflected from the deposit; and
transmitting an alert signal for maintenance to be performed.

16. The method of claim 15, wherein the light comprises wavelengths corresponding to red, green, and blue light.

17. The method of claim 15, wherein the light comprises wavelengths corresponding to infrared light.

18. The method of claim 15, wherein the processing comprises comparing the detected light to light detection data previously gathered and compiled through machine learning to determine that maintenance of the ion implantation system is due.

19. The method of claim 15, wherein in operation a vacuum is applied to a chamber immediately adjacent the outside face of the clear panel.

20. The method of claim 15, wherein the emitted light is from a multi-colored LED array and the detected light is detected by a photodiode, and the multi-colored LED array and the photodiode are situated immediately adjacent each other and oriented in the same direction.
